(19) United States
(12) Patent Application Publication
(10) Pub. No.: US 2010/0098853 A1
(43) Pub. Date: Apr. 22, 2010

(54) ARRANGEMENT FOR VAPORIZING MATERIALS AND METHOD FOR COATING SUBSTRATES

(75) Inventors: Uwe HOFFMANN, Alzenau (DE); Marcel MARTINI, Hanau (DE); Florian RIES, Westerngrund (DE); Elisabeth SOMMER, Alzenau (DE); Reiner GERTMANN, Linsengericht (DE)

Correspondence Address: PATTERSON & SHERIDAN, L.L.P., 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/256,421

(22) Filed: Oct. 22, 2008

(51) Int. Cl. C23C 16/44; C23C 16/54

(52) U.S. Cl. 427/255.6; 118/726

(57) ABSTRACT

The invention relates to an arrangement for the vaporization of materials, and specifically of organic materials, such as are utilized for example in the production of OLEDs. A heating element and a device for transporting a carrier for a layer to be vaporized are herein provided. The carrier with the layer to be vaporized is guided over the heating element where the layer is vaporized and deposited on a substrate.

### DESCRIPTION

The invention relates to an arrangement according to the preamble of patent claim 1 and a method according to the preamble of patent claim 13.

So-called displays are utilized in numerous fields of technology. The application range of such displays extends from cell phone displays through weather indicators up to television picture screens. Increasingly, the conventional cathode ray tube is more frequently replaced by liquid crystal or plasma displays.

For large-area display panels luminescence displays are preferably utilized which are comprised of several luminescence diodes. A luminescence diode is a p-n diode implemented as an optoelectronic semiconductor component in which at the p-n junction an electroluminescence occurs. Most often visible light is involved here, which is the reason why it is conventionally described as Light Emitting Diode (LED). For the production of such LEDs inorganic elements or compounds are exclusively used, for example GaAs:Si or GaP. Around the year 1953 it was discovered that electroluminescence can also occur in organic materials. But only starting in 1987 were attempts made to produce displays using OLEDs (Organic Light Emitting Diodes). When it was observed around 1990 that conjugated polymers, such as poly(p-phenylene vinylene), are suitable for use in organic light emitting diodes, increased attention was paid to OLEDs.

As a rule, two types of organic materials are utilized: long-chain molecules which are processed out of a solution, and small molecules which are thermally vapor-deposited under vacuum.

To the organic LEDs fabricated from polymers, the abbreviation PLED is widely applied. The OLEDs comprised of small molecules are often referred to as SOLEDs or SMOLEDs. In image quality and service life the small molecules are currently still superior to the polymers.

Thereby that OLEDs, in contrast to LEDs, can be applied onto nearly every material, for example onto flexible or transparent substrates, a multiplicity of new application feasibilities is opened up.

A further advantage of OLEDs is that they directly emit areally colored light. Thus, for the production of a display, for example some elements, such as color filters, diffusors, etc., can be omitted, which entails significant cost savings in their production.

Monochrome OLEDs, as a rule, are comprised of several layers. First, onto a substrate, for example a glass sheet, a conductive, light-permeable layer of indium-tin-oxide (ITO) is applied, which forms the lower electrode (anode). Thereon follows a hole conducting organic chemical layer (Hole Transport Layer=HTL). Then follows the emission layer proper, in which electrons and holes recombine, whereby light is generated. Hereupon follows an electron conducting layer (Electron Transport Layer=ETL). An aluminum layer forms the termination, which serves as upper electrode (cathode) and simultaneously reflects the upwardly directed light, such that the light finally emerges through the lower glass sheet (H. Lemme, Es strahlen die Wände, Elektronik, 12/2008, pp. 42-49). Depending on the production method, between ITO and HTL, often a layer of PEDOT/PSS (poly 3,4-ethylene dioxy thiophene) is additionally applied, which serves for lowering the injection barrier for holes and prevents the diffusion of indium into the junction. An important application field of these OLEDs are areal light sources, which are intended to replace incandescent and fluorescent lamps. The production of OLED displays is also possible. For the production of “white OLEDs” primarily two to three different emitting layers are utilized. By mixing the colors, while light is subsequently generated.

In coating substrates, organic material, which conventionally is available in powder form, is vaporized in a crucible of glass or metal.

The vapor is subsequently conducted to the substrate where it finally condenses and forms a uniform layer. When the material in a crucible is consumed, the crucible is replenished outside of the coating installation. The replenishing interrupts the coating process, which is undesirable. During the interruption the crucible must be cooled, flushed and uninstalled. Hereupon it is replenished and installed again. The entire crucible area must subsequently be evacuated and the crucible must be heated again. This procedure consumes several hours, i.e. the process stands still during this time.

A method for the production of a layer of a doped organic material on a substrate by means of deposition is already known, wherein the organic material comprises at least a matrix material and at least a doping material (EP 1 783 846 A1). At least one of the matrix or doping materials is herein incorporated in a porous carrier substance and vaporized out of this substance before it is converted into the vapor phase.

Furthermore is known a method for the continuous dry transfer of organic compounds onto webs of sheeting of air-permeable organic materials, wherein the organic compounds have a transfer temperature of 100° to 220° C. (DE 24 38 723 A1). The sheeting webs run here over several cylinders.

Known is also a release layer, a method for its production and use, which, for example, is utilized in the production of embossed film (EP 1 273 358 A2). Herein, for example, a substrate is coated with a release layer of organic monomers using vacuum technology and the release layer is subsequently detached using vacuum technology. For the realization of this coating, a band vapor deposition installation is provided, which comprises two coating chambers separated from one another by a partition wall. As in a conventional vapor deposition installation, two winding rollers are disposed in the band vapor deposition installation in order to wind a polymer color band from the feed-out roller onto the wind-up roller. The polymer color band is herein guided over a coating cylinder, a deflection roller as well as a vapor deposition cylinder. The coating of a band is consequently carried out in conventional manner thereby that the material reaches the band from vaporizers, which are heated and in which the medium to be vaporized is disposed.

Lastly is known a method for the vaporization of solids, in which several containers are provided which are filled with distinct materials (US 2006/0177578 A1). The material located in the container is a solid material and is fluidized. A vaporizer zone is provided which is disposed such that it is thermally insulated from the containers. The solid is herein transported into the vaporizer zone where it is vaporized.

The invention addresses the problem of carrying out a coating process over a very long time without interruption. The coating process can, for example, be carried out over one week without interruption and without the organic material being exposed to high temperatures for a long time.

This problem is solved according to the features of patent claims 1 and 13.

The invention consequently relates to an arrangement for vaporizing materials, and specifically of organic materials, such as, for example, are utilized in the production of OLEDs. Herein a heating element and a device for transporting a carrier for a layer to be vaporized are provided. The carrier with the layer to be vaporized is guided over the heating element where the layer is vaporized and is deposited on a substrate.

An advantage attained with the invention comprises that the complicated recharging of a crucible with material is superfluous when the material in the crucible has been consumed. Instead of a crucible, a coated band is utilized. Hereby the continuous material supply into the vaporization region is made feasible. This has the advantage that the process can be maintained for a longer period of time and the dwelling time of the organic material in the vaporization region is therein markedly shortened.

In addition, advantages accrue to the material producer. In the previous production methods the organic material is vaporized for the purpose of purifying it and condensed on a plate or the like. The organic material is subsequently scraped off this plate. This step can be omitted if the organic material in the last purification step is deposited directly on the carrier.

The invention thus relates to an arrangement for vaporizing materials, wherein said arrangement comprises a stationary heating element and a device for transporting a carrier relative to the stationary heating element, wherein this carrier is provided with a layer whose vaporization temperature is lower than the vaporization temperature of the carrier.

Furthermore, a method for coating substrates with vaporized organic material is described, said method comprising the steps of:

a) the organic material is applied onto a carrier,

b) the carrier with the organic material is transported into a vacuum chamber,

c) the organic material is vaporized,

d) the vaporized material is deposited on the substrate.

An embodiment example of the invention is shown in the drawing and will be explained in the following in further detail. In the drawing depict:

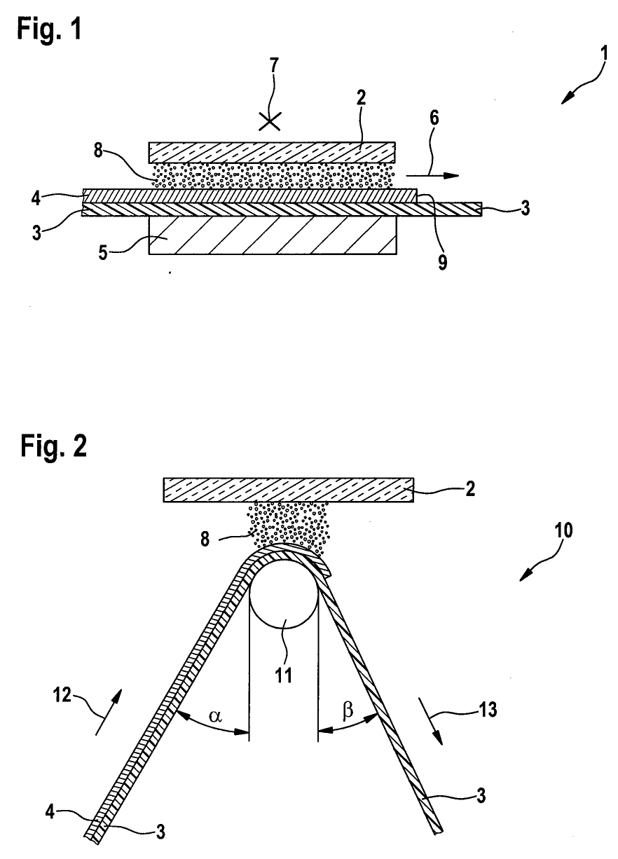

FIG. 1 a fundamental diagram of a first variant of a device for the vaporization of organic material,

FIG. 2 a fundamental diagram of a second variant of a device for the vaporization of organic material,

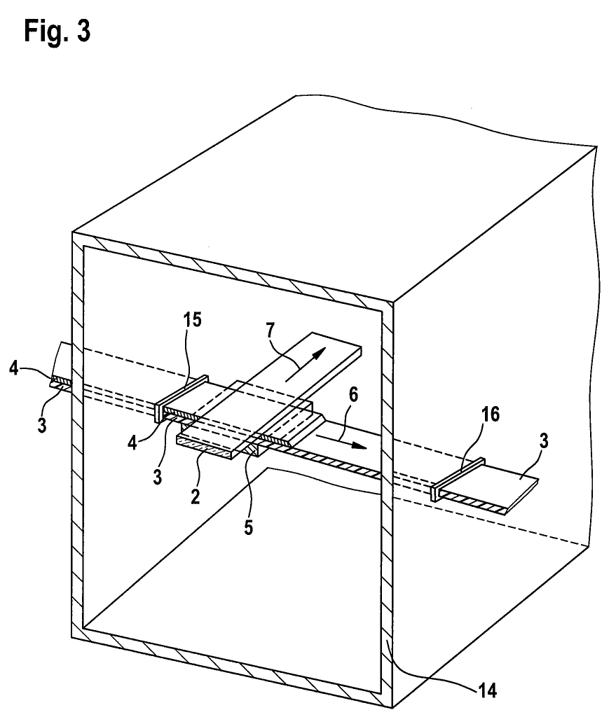

FIG. 3 a vaporization region with a vaporization device for organic material,

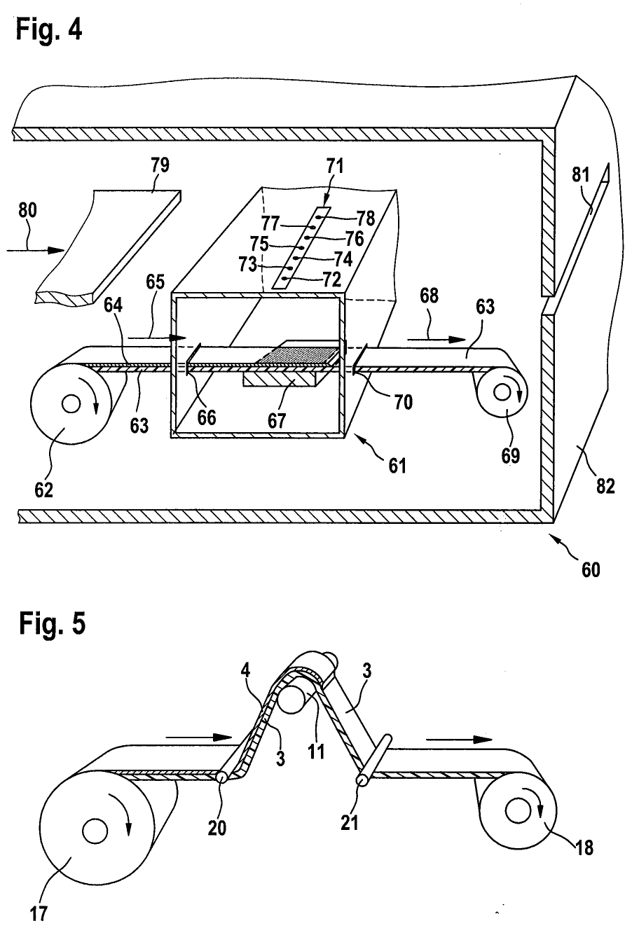

FIG. 4 a vaporization region according to FIG. 3 with feed-out and wind-up roller,

FIG. 5 a variant of the coating installation according to FIG. 4,

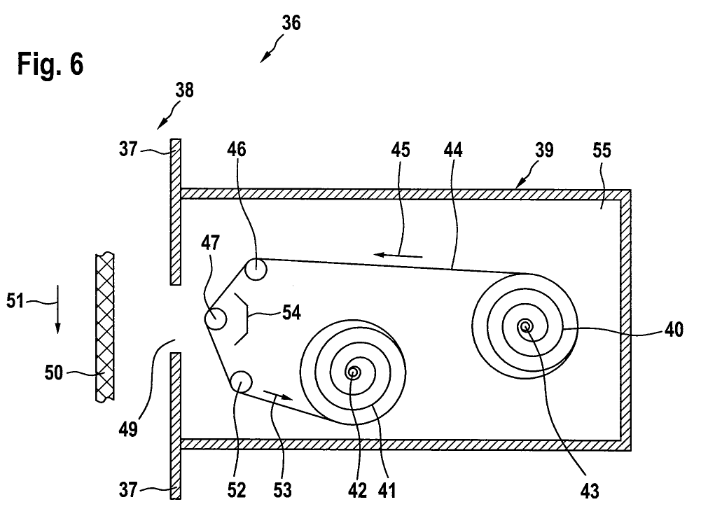

FIG. 6 a variant of a coating installation according to FIG. 4,

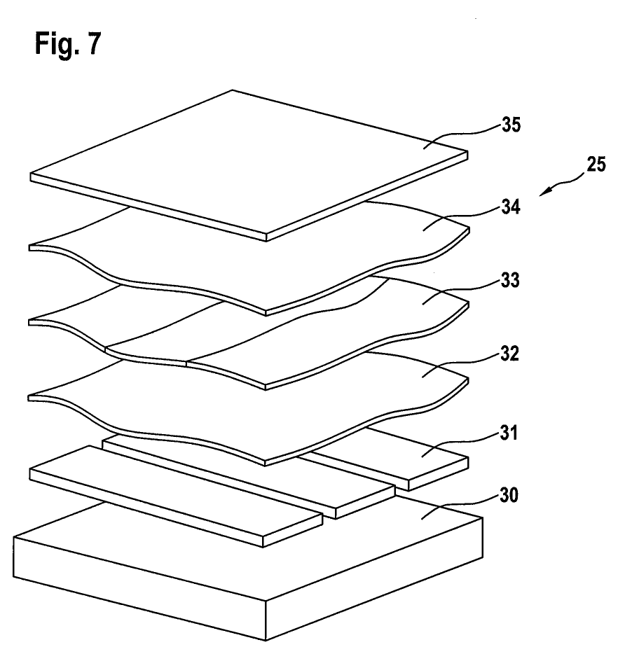

FIG. 7 a schematic representation of OLED structures.

FIG. 1 shows the principle of a vaporization device 1 with a substrate 2 on which a material is to be vapor deposited. The substrate 2 can be, for example, a glass sheet or an elastic film. A carrier 3 with organic material 4 rests on a heating plate 5 which can be disposed stationarily in the vaporizer device 1. Carrier 3 and organic material 4 are moved in the direction of an arrow 6, while the substrate 2 is moved into the plane of drawing, which is symbolized by an arrow end 7.

The combination of carrier 3, which is, for example, an elastic film of synthetic material or metal, and the organic material 4 is moved in the direction of arrow 6 over a heating plate 5 which is heated to a temperature at which the organic material 4 vaporizes and is deposited on the underside of the substrate 2. The vapor of organic material is denoted in FIG. 1 by the reference number 8.

Substrate 2 with the layer of organic material disposed on the underside of the substrate consequently serves for the production of electronic circuit components. If the electronic component is an OLED, it is also possible to refer to it generally as an organic circuit element.

When the combination of carrier 3 and organic material 4 reaches the right end of the heating plate 5, no more organic material 4 is located on the carrier 3.

FIG. 1 shows an abrupt end 9 of the organic material 4. However, in practice the layer thickness of the organic material 4 decreases quasi-linearly from the beginning of the heating plate 5 to its end. The temperature of the heating plate 5 is therefore set such that at the end of the transport path of the carrier 3 on the heating plate 5 no more organic material is found on the carrier.

FIG. 1 shows the vapor deposition on the substrate on its underside. However, it is also feasible to move the substrate vertically past the vaporizer sources. For this purpose the vaporizer is oriented vertically. A further feasibility comprises leaving the vaporizer source as shown in FIG. 1 and to connect a tube to it from which vapor exits in the vertical direction. The application field of this disposition is not limited to OLEDs, but rather can also be applied in the entire field of organic electronic circuitry, such as for example also in the field of organic photovoltaics.

In FIG. 2 is shown a second variant of a vaporizer device 10, with which organic material is vapor deposited on the substrate 2.

Instead of a heating plate, a heating cylinder 11 is here provided, over which runs the combination of carrier 3 and organic material 4. The heating cylinder 11 is also preferably disposed stationarily in the vaporizer device. The direction of motion of the combination toward the heating cylinder 11 is identified by an arrow 12, while the path away from the heating cylinder 11 is denoted by the reference number 13. The paths to it and the return paths form with a vertical plumb line the angles α or β, respectively. The carrier 3 in FIG. 2 is a band, however it can also be a wire, a film, a woven fabric or the like.

FIG. 3 shows a vaporization region corresponding to FIG. 1, wherein, however, the vaporization of the organic material 4 takes place within a vacuum chamber 14. It can be seen that the combination of the carrier 3 with the material 4 reaches the vacuum chamber 14 from the outside via a seal 15 and the carrier 3 without organic material is transported via the seal 16 from the vacuum chamber 14 into a region under atmospheric pressure.

FIG. 3 shows portions of carrier 3 and material 4 outside of the vacuum chamber 14. However, complete disposition within the vacuum chamber 14 is feasible. The chamber 14 must only include a shielded vaporization region. The feed-out as well as also the wind-up roller can be located within the chamber 14. This variant should be preferred whenever the material 4 must not come into contact with oxygen or air humidity for any length of time.

FIG. 4 shows a segment of a vacuum chamber 60 in which a vaporization region 61 is located. From a roller 62 a carrier 63, on which is disposed material 64 to be vaporized, is guided in the direction of an arrow 65 through an opening 66 of the vaporization region 61. The carrier 63 is here moved over a heating element 67 where the material 64 is vaporized. This heating element 67, for example, can be, as depicted in FIG. 4, a heating plate 67. After the material 64 has been vaporized, the carrier 63 is moved in the direction of arrow 68 until the carrier 63 is received on a roller 69. The carrier 63 is herein moved via an opening 70 out of the vaporization region 61. The vaporized material 64 exits the vaporization region 61 via a nozzle bar 71. This nozzle bar 71 includes a multiplicity of openings, of which openings 72 to 78 are evident. Evident is also a substrate 79 which is moved in the direction of an arrow 80. While moving the substrate 79 in the direction of arrow 80, the substrate 79 is also guided past the nozzle bar 71, whereby the vaporized material 64 can be deposited on the substrate 79. Via an opening 81 located in a wall 82 of the vacuum chamber 60 the substrate 79 is removed again from the vacuum chamber 60. This opening 81 can be, for example, an interlock gate.

Although in FIG. 4 only one nozzle bar 71 is provided, it is obvious to a person of skill in the art that, instead of a nozzle bar, a pipe system can also be provided which can guide the vapor to a vertically disposed distributor pipe. In this case the substrate is also guided vertically past the distributor pipe. Such a pipe system with a vertically disposed distributor pipe is disclosed, for example, in DE 102 24 908 A1.

FIG. 5 shows an arrangement which includes a heating system corresponding to FIG. 2. Again, the heating cylinder 11 is evident, which is comprised, for example, of ceramics. From a roller 17 the carrier 3 with the organic material 4 is guided over the heating cylinder 11. There the material 4 is evaporated.

In addition, two deflection rollers 20, 21 are provided which deflect the combination of carrier 3 and organic material 4 or the carrier 3 without organic material, respectively. The carrier 3 without the material 4 is then received on a roller 18. This arrangement is located in a vacuum chamber not shown here.

FIG. 6 shows a section of a variant of a coating installation 36 according to the coating installation shown in FIG. 4. Evident is a portion of a wall 37 of a vacuum chamber 38 of the coating installation 36. On the wall 37 of the vacuum chamber 38 is disposed a cassette 39. This cassette 39 is preferably disposed in the vacuum chamber 38 such that it is removable in order for this cassette 39 to be readily exchanged for another cassette. In the cassette 39 can be seen two rollers 40, 41, each disposed on an axle 42, 43, respectively. On the first roller 40 is located a combination of carrier 3 and organic material 4, as is shown in FIG. 1 to 4. The carrier 3 is herein disposed as a band 44 on the roller 40. This band 44 runs in the direction of arrow 45 to a deflection roller 46. Over this deflection roller 46 the carrier 3 runs further in the direction of a heatable roller 47 which can be comprised, for example, of ceramics. On this heatable roller 47 the organic material is vaporized. This vapor exits the interior 55 of the cassette 39 through an opening 49 of the vacuum chamber 38 and in this way arrives on a substrate 50. This substrate 50 is moved in the direction of arrow 51 past the opening 49 of the vacuum chamber 38. Although not shown in FIG. 6, the vacuum chamber 38 has a gate or a sliding valve with which the opening 49 can be closed if needed. Over a further deflection roller 52 the carrier 3 is wound onto roller 41 in the direction of arrow 53. Since the organic material 4 is already vaporized on the heatable roller 47, consequently on roller 41 the carrier 3 without the organic material is wound. On roller 41 thus the empty carrier 3 is disposed. In the cassette 39 is preferably disposed a heat shield 54 which at least partially encompasses the heatable roller 47. Of advantage in this variant is that the cassette 39 can be simply removed after the organic material 4 on carrier 3 has been vaporized. This cassette 39 can subsequently be exchanged for another cassette. Opening 49 can herein be implemented as an interlock. The cassette 39 can thereby be exchanged for another one without the process having to be interrupted. That means that the vacuum in the vacuum chamber 38 is maintained. Consequently, the advantage in this variant is that the vacuum chamber 38 does not have to be opened in order to replace an empty carrier with a carrier with organic material.

FIG. 7 depicts a schematic representation of an OLED structure 25, such as is utilized, for example, in a television display.

This OLED structure 25 is comprised of a substrate 30, for example a substrate of glass, with several layers disposed thereon. Directly on the substrate 30 is disposed an anode 31, which can be comprised, for example, of ITO. On this anode 31 is disposed a layer 32 of a hole conductor. On layer 32 is disposed an emitter layer 33, on which, in turn, an electron conducting layer 34 is disposed. On this layer 34 is disposed the cathode 35. This cathode 35 is comprised of a metal with low electrode work function, such as, for example, calcium, aluminum, barium, ruthenium, magnesium, silver or their alloys.

1. Arrangement for vaporizing materials, characterized by
a) a stationary heating element,
b) a device for transporting a carrier relative to the stationary heating element, wherein this carrier is provided with a layer whose vaporization temperature is lower than the vaporization temperature of the carrier.

2. Arrangement as claimed in claim 1, characterized in that the stationary heating element is a heating plate.

3. Arrangement as claimed in claim 1, characterized in that the stationary heating element is a heating cylinder.

4. Arrangement as claimed in claim 1, characterized in that the carrier is a band.

5. Arrangement as claimed in claim 1, characterized in that the carrier is a wire.

6. Arrangement as claimed in claim 1, characterized in that the carrier is comprised of a woven material.

7. Arrangement as claimed in claim 1, characterized in that the carrier is a film.

8. Arrangement as claimed in claim 1, characterized in that the layer is an organic layer.

9. Arrangement as claimed in claim 3, characterized in that at least the carrier forms with a line perpendicular to the rotational axis of the heating cylinder an angle α or β.

10. Arrangement as claimed in claim 9, characterized in that the angles α or β, respectively, are determined by means of deflection rollers.

11. Arrangement as claimed in claim 1, characterized in that a substrate is provided which is disposed adjacent to the layer.

12. Arrangement as claimed in claim 1, characterized in that the carrier and layer are disposed on a first roller within a vaporizer chamber and the carrier without the layer is disposed on a second roller within the vaporizer chamber.

13. Method for coating substrates with vaporized organic material, characterized by the following steps:
a) the organic material is applied onto a carrier,
b) the carrier with the organic material is transported into a vacuum chamber,
c) the organic material is vaporized,
d) the vaporized material is deposited on the substrate

14. Method as claimed in claim 13, characterized in that the carrier with the organic material is set into the vacuum chamber as a roller.

15. Method as claimed in claim 13, characterized in that the carrier with the organic material is disposed in a cassette which is disposed on the vacuum chamber.

16. Method as claimed in claim 13, characterized in that the carrier with the organic material is disposed in a cassette which is disposed in the vacuum chamber.
